(19) United States
(12) Patent Application Publication
(10) Pub. No.: US 2017/0084472 A1
(43) Pub. Date: Mar. 23, 2017

(54) MANIPULATOR

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Jinkun LI, Beijing (CN); Guoming GUO, Beijing (CN); Nanxuan GU, Beijing (CN); Jian HOU, Beijing (CN); Shuyu LIU, Beijing (CN); Min LIU, Beijing (CN); Xikui HAO, Beijing (CN)

(73) Assignees: BOE TECHNOLOGY GROUP CO., LTD., Beijing (CN); HEFEI XINSHENG OPTOELECTRONICS TECHNOLOGY CO., LTD., Anhui (CN)

(21) Appl. No.: 15/147,637

(22) Filed: May 5, 2016

(30) Foreign Application Priority Data
Sep. 23, 2015 (CN) 201510614207.2

(51) Int. Cl. H01L 21/67; H01L 21/677; B25J 15/00

(52) U.S. Cl. CPC H01L 21/67196; B25J 15/0014; H01L 21/67742; H01L 21/67748

(57) ABSTRACT

The present disclosure provides a manipulator mounted between a first chamber and a second chamber of a vacuum reaction apparatus for moving a plate material from the first chamber to the second chamber. The manipulator comprises: a first supporting structure on which a rail is provided along a first direction in a horizontal plane, wherein the first chamber and the second chamber are respectively positioned at two opposite ends of the rail; an arm mounted on the first mounting structure for bearing the plate material, wherein the arm is movable along the rail; and a vertically mechanism on which the first supporting structure and the arm are mounted, wherein the vertically mechanism is capable of driving the first supporting structure and the arm to move in a vertical direction.

### CROSS-REFERENCE TO RELATED APPLICATION

The present application claims priority to Chinese patent application No. 201510614207.2 filed on Sep. 23, 2015, which is incorporated herein by reference in its entirety.

### TECHNICAL FIELD

The present disclosure relates to the field of automation, in particular to a manipulator.

### BACKGROUND

At present, during the manufacturing of TFT-LCD (Thin Film Transistor-Liquid Crystal Display), the vacuum reaction apparatus in use is shown in FIG. 1, which comprises a vacuum transition chamber, a transfer chamber, and at least one reaction chamber, wherein the transfer chamber is connected with the vacuum transition chamber and each of the reaction chambers, respectively. A manipulator is provided in the transfer chamber. Using the manipulator allow plate-like product, for example, substrate, to be circulated between the vacuum transition chamber and each of the reaction chambers.

As shown in FIG. 2, an existing manipulator 10 comprises a first supporting structure 11, a second supporting structure 12, a third supporting structure 13 and an arm 14. Wherein the first supporting structure 11 is rotatable in a horizontal plane (wherein x-axis and y-axis are located), the second supporting structure 12 is movable upward and downward in a direction of z-axis, and the third supporting structure 13 is movable forward and backward in a direction of x-axis and also leftward and rightward in a direction of y-axis.

Specifically, in the transfer chamber, the specific positions of the arm 14 in the directions of x-axis, y-axis and z-axis can be respectively adjusted by the manipulator 10 by means of adjusting the second supporting structure 12 and the third supporting structure 13. The arm 14 can take the substrate out of the vacuum transition chamber and then rotated by the first supporting structure 11 about 180 degree in the direction of x-axis so that places the substrate in the reaction chamber.

The inventors found existing manipulators have the following problems in the course of picking and placing substrate: on one hand, there is a risk that the substrate may dropping down from the arm 14 during rotation of the first supporting structure 11, and therefore reduce the yield of product; on the other hand, considering the large length of the arm 14 and the width of the transfer chamber needs to be greater than the length of two arms, it is required that the transfer chamber must has a larger volume.

### SUMMARY

The embodiment of the present disclosure provides a manipulator, which can pick and place articles in a small space without rotation and can therefore increase the yield of product.

In order to achieve the above-described object, the embodiment of the present disclosure adopts the following technical solutions.

The embodiment of the present disclosure provides a manipulator mounted between a first chamber and a second chamber of a vacuum reaction apparatus for moving a plate material from the first chamber to the second chamber, wherein the manipulator comprises:
a first supporting structure on which a rail is provided along a first direction in a horizontal plane, wherein the first chamber and the second chamber are respectively positioned at two opposite ends of the rail;
an arm mounted on the first supporting structure for bearing the plate material, the arm is movable along the rail;
a vertically movable mechanism on which the first supporting structure and the arm are mounted, wherein the vertically movable mechanism is capable of driving the first supporting structure and the arm to move in a vertical direction.

Preferably, the manipulator further comprising a horizontally movable mechanism on which the vertically movable mechanism is mounted, wherein the horizontally movable mechanism is capable of driving the vertically movable mechanism to move in a second direction in the horizontal plane, wherein the first direction is perpendicular to the second direction.

Preferably, the horizontally movable mechanism is further capable of driving the first supporting structure and the arm to move in the first direction in the horizontal plane.

Preferably, the rail is a groove and the arm is provided with a movable member which is movable along the groove.

Preferably, the groove dodoes not penetrate the first supporting structure.

Preferably, side faces of the groove are bent faces, and side faces of the movable member are embedded into the side faces of the groove.

Preferably, the side faces of the groove are bent inward and the side faces of the movable member are bent in the same direction as the side faces of the groove.

Preferably, the rail is a slide rail and the arm is provided with a slide wheel which is movable along the slide rail.

Preferably, the rail is a magnetic rail and the arm is a device provided for magnetic absorption.

Preferably, the arm is not in contact with an upper surface of the first supporting structure.

Preferably, the manipulator comprises two arms which are respectively provided on two first supporting structures, and the two first supporting structures are spaced apart from each other at a certain distance.

Preferably, a bearing surface of the manipulator is provided with an absorption device which absorbs the plate material onto the arm.

The arm of the manipulator provided in the embodiment of the present disclosure is slidable in the direction of x-axis, and this movement in combination with vertical movement thereof in the direction of z-axis can completing the actions of taking the display substrate out of the first chamber and placing it in the second chamber. As compared with the arm of the existing manipulator which placing the display substrate into the second chamber by rotation after taking it out of the first chamber, the present disclosure can reduce the risk of dropping the display substrate, improve the yield of product, effectively save transfer space and design cost, and also increase the activation for transferring the display substrate.

### BRIEF DESCRIPTION OF THE DRAWINGS

In order to illustrate the embodiment of the present disclosure or the technical solution in the prior art more clearly, the drawings used in descriptions of the embodiment or the prior art will be simply described in the following. Obviously, the drawings described below only show some of the embodiments of the present disclosure. It will be apparent to those skilled in the art that other drawings can be obtained base on these drawings without involving inventive work.

FIG. 1 is a schematic view showing an existing vacuum reaction apparatus:

FIG. 2 is a schematic view showing an existing manipulator;

FIG. 3 is a schematic view showing a manipulator according to some embodiment of the present disclosure:

FIG. 4 is a schematic view showing an arm of the manipulator when taking and placing a plate material according to some embodiment of the present disclosure.

FIG. 5 is a schematic view showing another manipulator according to some embodiment of the present disclosure;

FIG. 6 is a schematic view showing a rail according to some embodiment of the present disclosure:

FIG. 7 is a schematic view showing an arm according to some embodiment of the present disclosure;

FIG. 8 is a schematic view showing another manipulator according to some embodiment of the present disclosure:

FIG. 9 is a schematic view showing another rail according to some embodiment of the present disclosure; and

FIG. 10 is a schematic view showing an arm according to some embodiment of the present disclosure.

### REFERENCE SIGNS

10—manipulator; 11—first supporting structure; 12—second supporting structure; 13—third supporting structure; 14—arm; 15—vertically movable mechanism; 16—horizontally movable mechanism; 20—display substrate; 111—rail; 111′—magnetic rail; 141—movable member; 142—absorption device.

### DETAILED DESCRIPTION

The technical solution in the embodiments of the present disclosure will be described hereinafter clearly and entirely in conjunction with the drawings. Obviously, the embodiments described herein are a part of, but not all of the embodiments of the present disclosure. Based on the embodiment of the present disclosure, all other embodiment s obtained by a person skilled in the art without involving inventive work shall fall into the protection scope of the present disclosure.

An embodiment of the present disclosure provides a manipulator mounted between a first chamber and a second chamber of a vacuum reaction apparatus for moving a plate material in the first chamber to the second chamber. As shown in FIG. 3, a manipulator 10 comprises:
a first supporting structure 11 provided with a rail 111 thereon in a first direction 101 in a horizontal plane, wherein the first chamber and the second chamber are respectively positioned at two opposite ends of the rail 111;
an arm 14 mounted on the first supporting structure 11 for bearing the plate material, the arm 14 is movable along the rail 111;
a vertically movable mechanism 15 on which the first supporting structure 11 and the arm 14 are mounted, the vertically movable mechanism 15 can drive the first supporting structure 11 and the arm 14 to move in a vertical direction (direction of z-axis).

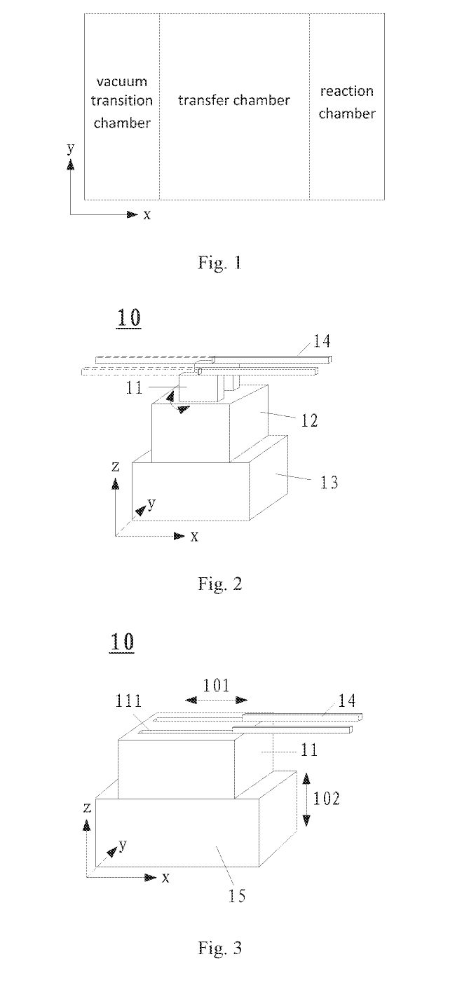

It should be noted that the first supporting structure 11 is provided with the rail 111 thereon in the first direction in the horizontal plane, and the first chamber and the second chamber are respectively positioned at two opposite ends of the rail 111. In FIG. 3, the first direction 101 is the direction of x-axis, and the first chamber and the second chamber are respectively positioned at two opposite ends of the rail, i.e., the first chamber and the second chamber are respectively positioned at two opposite ends of the manipulator 10 in the direction of x-axis. Since the manipulator 10 is mounted between the first chamber and the second chamber of the vacuum reaction apparatus, the first chamber may be a vacuum transition chamber as shown in FIG. 1, the second chamber may be a reaction chamber, and the manipulator 10 may be positioned in a transfer chamber. The vertically movable mechanism 15 is capable of driving the first supporting structure 11 and the arm 14 to move in the direction of z-axis, i.e., a direction 102 as shown in FIG. 3.

It should be noted that the embodiment of the present disclosure is described by taking the example of display substrate as the plate material. The display substrate is supported and placed in the first chamber and the second chamber, for example, by the arm 14 of the manipulator 10. The arm 14 of the manipulator 10 is moved downward in the direction of z-axis by the vertically movable mechanism 15 so as to be located under the plate material to be taken in the first chamber, and the arm 14 is moved to the first chamber along the rail 11 and then it is moved upward along the direction of z-axis by means of the vertically movable mechanism 15, so as to hold the plate material in the first chamber on the arm 14. Next, the arm 14 is moved along the rail 11 so that the plate material thereon is located in the second transition chamber, and the arm 14 of the manipulator 10 is located above a supporting structure of the plate material in the second chamber and then it is moved downward along the direction of z-axis by means of the vertically movable mechanism 15, so as to place the plate material on the supporting structure in the second chamber. Now, the operation of moving the plate material from the first chamber to the second chamber is completed by the manipulator 10.

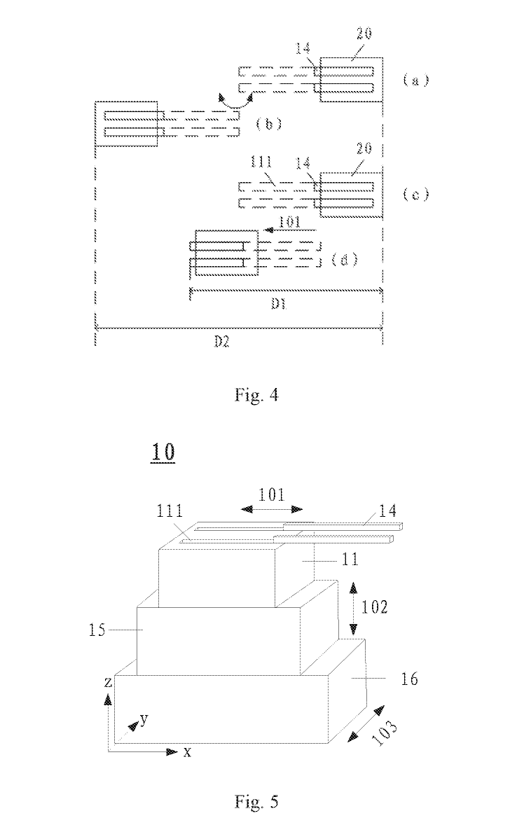

Now refer to FIG. 4, when the arm of the existing manipulator needs to take out a display substrate, as shown in FIGS. 4(a) and 4(b), the display substrate 20 is firstly positioned on the arm 14 in the first chamber and then it is transferred by rotation. A space length required for the display substrate 20 to move from one side of the manipulator to its opposite side in the prior art is D2. When the manipulator in the embodiment of the present disclosure needs to take out a display substrate, as shown in FIG. 4(c), the display substrate 20 is firstly positioned on the arm 14 in the first chamber, and then, as shown in FIG. 4(d), the arm 14 slides along the rail 111 to move the display substrate 20 to the second chamber. A space length required for the display substrate 20 to move from one side of the manipulator to its opposite side in the present disclosure is D1, and D1<D2. That is, as compared with the arm of the existing manipulator as shown in FIG. 2 that transfers the display substrate by means of rotation, the manipulator in the embodiment of the present disclosure can greatly save transfer space and design cost, increase the activation for transferring the display substrate, reduce the risk of dropping the display substrate during rotation, and improve the yield of product.

According to the manipulator in the embodiment of the present disclosure, its arm is slidable in the direction of x-axis, and can complete the actions of taking the display substrate out of the first chamber and placing it in the second chamber in combination with the vertical movement in the direction of z-axis. As compared with the arm of the existing manipulator which placing the display substrate into the second chamber by rotation after taking it out of the first chamber, he present disclosure can reduce the risk of dropping the display substrate, improve the yield of product, effectively save transfer space and design cost, and meanwhile increase the activation for the transferring the display substrate. On the other hand, it is not necessary for the manipulator in the embodiment of the present disclosure to be provided with a selection device as compared with the existing manipulator, and therefore, it has a simple structure and easy to maintain.

Preferably, as shown in FIG. 5, the manipulator 10 further comprises a horizontally movable mechanism 16. The first supporting structure 11 and the arm 14 are mounted on the vertically movable mechanism 15, and the vertically movable mechanism 15 is mounted on the horizontally movable mechanism 16. The horizontally movable mechanism 16 is capable of driving the vertically movable mechanism 15 to move in a second direction in the horizontal plane, i.e., the direction of y-axis (a direction 103 as shown in FIG. 5), wherein the first direction is perpendicular to the second direction. That is, the direction of x-axis is perpendicular to the direction of y-axis. As shown in FIG. 5, since the horizontally movable mechanism 16 is movable in the direction of y-axis, the arm 14 of the manipulator 10 is movable in the direction of x-axis along the rail 111, movable in the direction of z-axis under the driving of the vertically movable mechanism 15, and movable in the direction of y-axis under the driving of the horizontally movable mechanism. Therefore, the manipulator can realize both horizontal and vertical movements.

Further preferably, as shown in FIG. 5, the horizontally movable mechanism 16 further capable of driving the vertically movable mechanism 15 to move in the first direction in the horizontal plane, i.e., the direction of x-axis. Since the rail 111 is provided on the first supporting structure 11, a distance of the arm 14 sliding in the direction of x-axis is limited. The horizontally movable mechanism is further capable of driving the arm 14 to move in the direction of x-axis so that the arm 14 of the manipulator 10 can reach a further position in the direction of x-axis, therefore improve the flexibility of using the manipulator.

Preferably, as shown in FIGS. 3 and 5, the rail 111 is a groove. As shown in FIG. 7, the arm 14 is provided with a movable member 141, which is movable along the groove 111. Preferably, as shown in FIGS. 3 and 5, the groove dose not penetrate the first supporting structure 11 so as to prevent the movable member from completely sliding out of the groove.

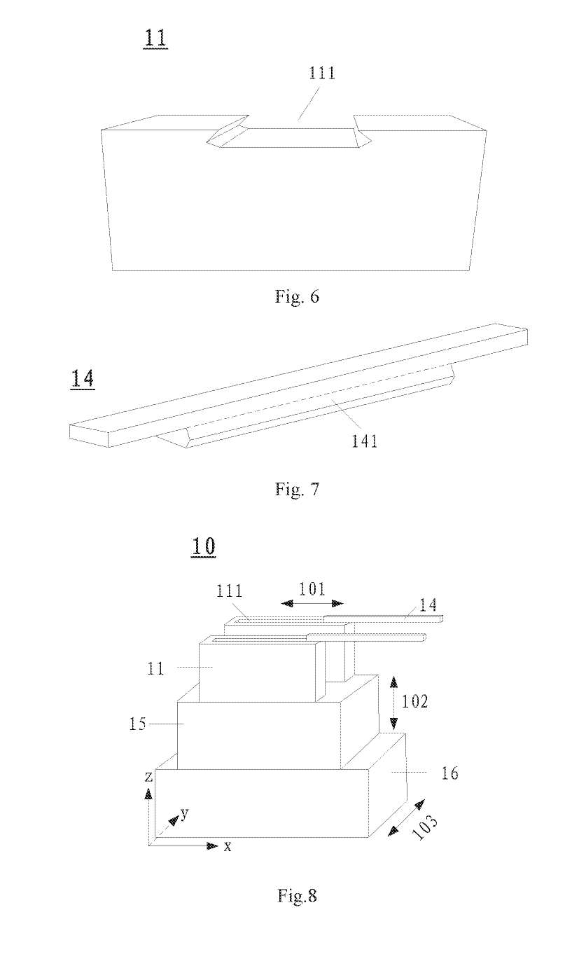

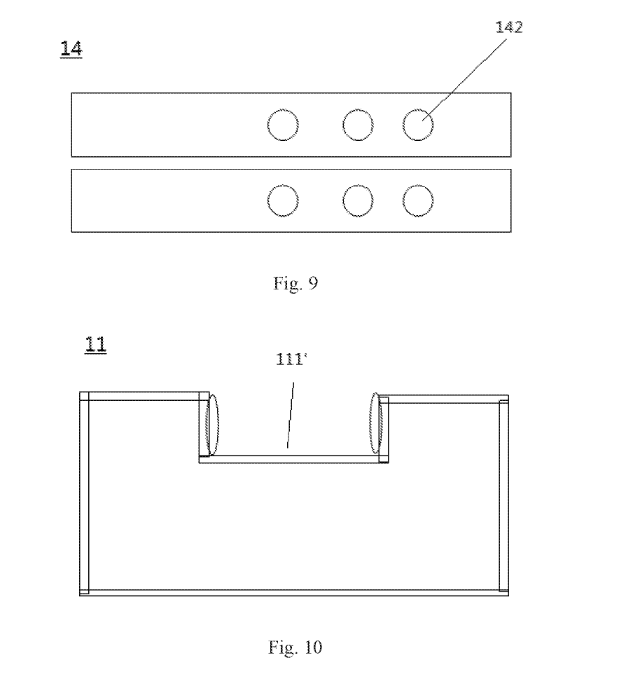

Preferably, as shown in FIG. 6, side faces of the groove 111 are bent faces, and side faces of the movable member 141 are embedded into the side faces of the groove. Wherein the side faces of the groove in FIG. 6 are bent inward and the side faces of the movable member 141 in FIG. 7 are bent in the same direction as the side faces of the groove, so that the side faces of the movable member 141 are embedded into the side faces of the groove 111. Therefore, the movable member 141 can be embedded into the groove.

Or, the rail is a slide rail and the arm is provided with a slide wheel which is movable along the slide rail. Further, the slide rail is provided on an upper surface of the first supporting structure. The arm is not in contact with the upper surface of the first supporting structure.

Because the supporting structures for fixing the plate material in the first chamber and the second chamber are often as the same as the arm, if the arm is not in contact with the upper surface of the first supporting structure, then the supporting structures for fixing the plate material in the first chamber and the second chamber can be interposed between two arms, therefore the plate material can be conveniently placed in a desired position.

It should be noted that the arm is moved along the rail, and structures of the arm and the rail are not limited to the above-described two forms. For example, the rail may further be a magnetic rail 111′, and the arm may be a device provided for magnetic absorption so as to be moved along the magnetic rail 111′.

Preferably, as shown in FIG. 8, the manipulator 10 comprises two arms 14 which are respectively provided on two first supporting structures 11, and the two first supporting structures 11 are spaced apart from each other at a certain distance. That is, the supporting structures for fixing the plate material in the first chamber and the second chamber may further be located between the two first supporting structures, therefore facilitate taking and placing of the plate material.

Preferably, a bearing surface of the manipulator is provided with an absorption device 142, which absorbs the plate material on the arm. That is, the absorption device 142, which is provided on the bearing surface of the arm, absorbs the plate material on the arm, so as to further avoid dropping of the plate material from the arm and reduce the loss.

The above description only shows the specific embodiments of the present disclosure, but the protection scope of the present disclosure is not limited to the above. It will be apparent to those skilled in the art that various variations or replacements can be made within the technical scope of the present disclosure, and all these variations and replacements shall fall into the protection scope of the present disclosure. Therefore, the protection scope of the present disclosure shall be determined by the terms of the claims.

What is claimed is:

1. A manipulator mounted between a first chamber and a second chamber of a vacuum reaction apparatus for moving a plate material from the first chamber to the second chamber, wherein the manipulator comprises:
a first supporting structure on which a rail is provided along a first direction in a horizontal plane, wherein the first chamber and the second chamber are respectively positioned at two opposite ends of the rail;
an arm mounted on the first supporting structure for bearing the plate material, wherein the arm is movable along the rail; and
a vertically movable mechanism on which the first supporting structure and the arm are mounted, wherein the vertically movable mechanism is capable of driving the first supporting structure and the arm to move in a vertical direction.

2. The manipulator according to claim 1, further comprising a horizontally movable mechanism on which the vertically movable mechanism is mounted, wherein the horizontally movable mechanism is capable of driving the vertically movable mechanism to move in a second direction in the horizontal plane, wherein the first direction is perpendicular to the second direction.

3. The manipulator according to claim 2, wherein the horizontally movable mechanism is further capable of driving the vertically movable mechanism to move in the first direction in the horizontal plane.

4. The manipulator according to claim 1, wherein the rail is a groove and the arm is provided with a movable member which is movable along the groove.

5. The manipulator according to claim 4, wherein the groove dose not penetrate the first supporting structure.

6. The manipulator according to claim 4, wherein side faces of the groove are bent faces, and side faces of the movable member are embedded into the side faces of the groove.

7. The manipulator according to claim 5, wherein side faces of the groove are bent faces, and side faces of the movable member are embedded into the side faces of the groove.

8. The manipulator according to claim 6, wherein the side faces of the groove are bent inward and the side faces of the movable member are bent in the same direction as the side faces of the groove.

9. The manipulator according to claim 1, wherein the rail is a slide rail and the arm is provided with a slide wheel which is movable along the slide rail.

10. The manipulator according to claim 1, wherein the rail is a magnetic rail and the arm is a device provided for magnetic absorption.

11. The manipulator according to claim 9, wherein the arm is not in contact with an upper surface of the first supporting structure.

12. The manipulator according to claim 1, further comprising two arms which are respectively provided on two first supporting structures, and the two first supporting structures are spaced apart from each other at a certain distance.

13. The manipulators according to claim 1, wherein a bearing surface of the manipulator is provided with an absorption device which absorbs the plate material onto the arm.
